(19) United States
(12) Patent Application Publication
(10) Pub. No.: US 2006/0148201 A1
(43) Pub. Date: Jul. 6, 2006

(54) Method for forming an STI in a flash memory device

(75) Inventor: Dong-Oog Kim, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DONGBUANAM SEMICONDUCTOR INC.

(21) Appl. No.: 11/320,607

(22) Filed: Dec. 30, 2005

(30) Foreign Application Priority Data
Dec. 30, 2004 (KR) 10-2004-0117159

(51) Int. Cl. H01L 21/76

(52) U.S. Cl. 438/424; 438/435

(57) ABSTRACT

The present invention provides a method of forming an STI region in a flash memory device. The method includes: forming a pad oxide layer on a semiconductor substrate; forming a hard mask on the pad oxide layer; forming a recess groove below the hard mask by etching a portion of the pad oxide layer exposed by the hard mask and a portion of the pad oxide layer below the hard mask; forming a trench having a round edge by etching a portion of the semiconductor substrate exposed by the hard mask and a portion of the semiconductor substrate exposed in the recess groove; and forming an insulation layer filling in the trench.

### CROSS-REFERENCE TO RELATED APPLICATION

This application claims priority to and the benefit of Korean Patent Application No. 10-2004-0117159 filed in the Korean Intellectual Property Office on Dec. 30, 2004, the entire contents of which are incorporated herein by reference.

### BACKGROUND OF THE INVENTION

(a) Field of the Invention

The present invention relates to a semiconductor device, and more particularly to a method of forming an insulation layer so as to fill in a gate in a flash memory device.

(b) Description of the Related Art

A NOR type of flash memory device is a non-volatile memory device having a floating gate and a control gate in its stacked structure. A stacked structure including a floating gate and a control gate is formed in a dual conductive polysilicon structure. The stacked structure is formed on a tunnel oxide layer. An ONO (Oxide—Nitride—Oxide) layer used as a dielectric layer is formed between a floating gate and a control gate. The ONO layer performs a function of a capacitor. According to a coupling ratio, a bias applied at a control gate can be applied at a floating gate through an ONO layer. Program and erase operations for a flash memory are performed by using a relatively high bias.

FIG. 1A to FIG. 1C are drawings showing a conventional method of forming a shallow trench isolation (STI) region in a flash memory device.

FIG. 1A is a top plan view briefly showing a layout of a conventional flash memory device, and FIG. 1B and FIG. 1C are cross-sectional views respectively showing a section for a bit line direction and for a word line direction. According to a conventional method of forming a flash memory device, a field region 15 defining an active region 11 is formed on a semiconductor substrate 10 by forming a shallow trench isolation (STI) region. In addition, a tunnel oxide layer 22, a floating gate 21, a dielectric layer 24, and a control gate 25 are formed on the active region 11. A wordline 20, namely a gate, crosses a bit line, and a single cell is formed at a crossing point between the word line 20 and the bit line. In addition, a bit line contact 30 and a drain contact are formed at an end of the active region 11.

However, according to a conventional method of forming an STI region, an edge of the field region 15 is formed in an acute shape having a sharp angle. The main reason for the acute edge of the field region 15 is that, even if a flash cell is formed by using a design rule of 0.18 μm or less, the active region 11 and the field region 15 are actually formed by respectively using a design rule of 0.22 μm or less and 0.14 μm or less in order to reduce a cell size. That is, even if the cell size is reduced, the field region 15 has a relatively small width in order for the active region 11 to have a relatively large width.

Therefore, since the edge of the field region 15 has a sharp profile having an acute angle, several defects are induced by such a sharp profile. For example, an over-erase defect may be induced by such a sharp profile of the edge of the field region 15. When an erase operation for a NOR flash memory cell is performed by using an FN tunneling method, charges in the floating gate 21 escape into the substrate 10. However, the edge of the field region 15 having an acute angle may induce the over-erase defect because charges in portions adjacent to the edge of the field region 15 may unexpectedly escape into the substrate 10. In addition, charges in the floating gate 21 may escape through only one side of the floating gate 21 because they cannot uniformly escape into the substrate 10.

Therefore, a profile of the STI field region 15 is preferentially required to be improved so as to overcome such operation defects of the flash memory device.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a method of forming an STI in a flash memory device having advantages of enhancing operation characteristics of a flash memory device by improving a profile in a field region of the flash memory device.

An exemplary method of an STI in a flash memory device according to an embodiment of the present invention includes: forming a pad oxide layer on a semiconductor substrate; forming a hard mask on the pad oxide layer; forming a recess groove below the hard mask by etching a portion of the pad oxide layer exposed by the hard mask and a portion of the pad oxide layer below the hard mask; forming a trench having a round edge by etching a portion of the semiconductor substrate exposed by the hard mask and a portion of the semiconductor substrate exposed in the recess groove; and forming an insulation layer filling in the trench.

The hard mask may include a silicon nitride layer.

The forming of the recess groove may be performed by an isotropic etching process for a portion of the pad oxide layer exposed by the hard mask and a portion of the pad oxide layer below the hard mask.

The isotropic etching for the pad oxide layer may be performed by wet etching with the use of an etchant including hydrofluoric acid.

The wet etching with the use of an etchant including hydrofluoric acid may be performed by using an oxide layer having a thickness of about 250 Å as an etching target.

The forming of the trench may be performed by isotropic etching with the use of a chemical dry etch (CDE) scheme.

The filling of the trench with the insulation layer may be performed by depositing an HDP-USG (High Density Plasma-Undoped silicate glass) material.

Before the filling of the trench with the insulation layer, a buffer layer may be formed on sidewalls of the trench.

According to an exemplary embodiment of the present invention, operation characteristics of a flash memory device may be enhanced by improving a profile in a field region of the flash memory device.

### BRIEF DESCRIPTION OF THE DRAWINGS

FIG. 1A to FIG. 1C are drawings showing a conventional method of forming an STI in a flash memory device.

FIG. 2 to FIG. 5 are cross-sectional views showing a method of forming an STI in a flash memory device according to an exemplary embodiment of the present invention.

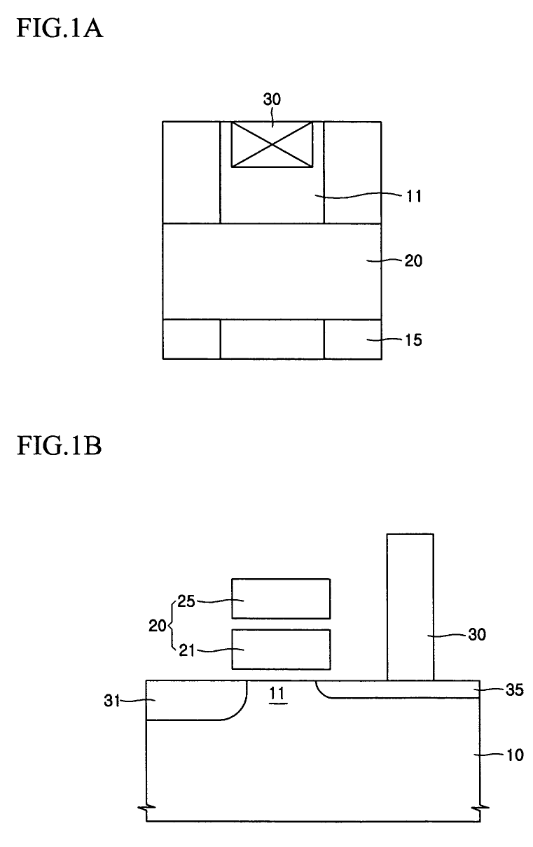

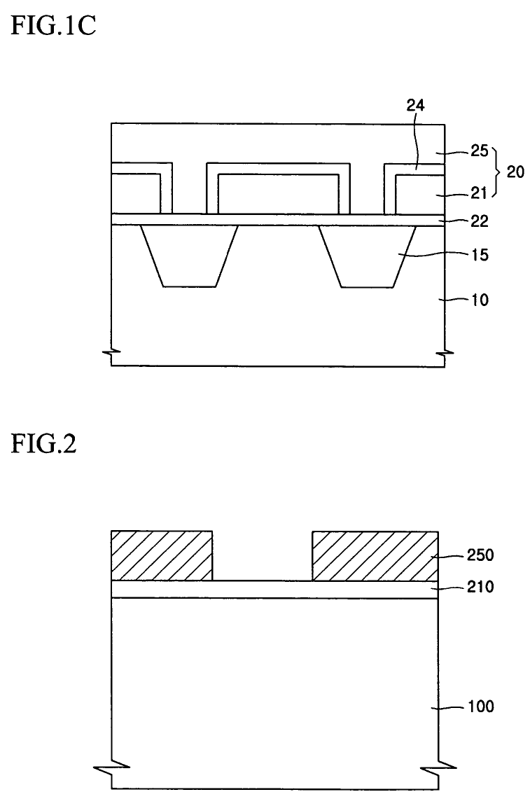

### DETAILED DESCRIPTION OF THE EMBODIMENTS

With reference to the accompanying drawings, the present invention will be described in order for those skilled in the art to be able to implement the invention. As those skilled in the art would realize, the described embodiments may be modified in various different ways, all without departing from the spirit or scope of the present invention.

To clarify multiple layers and regions, the thicknesses of the layers are enlarged in the drawings. Like reference numerals designate like elements throughout the specification. When it is said that any part, such as a layer, film, area, or plate is positioned on another part, it means the part is directly on the other part or above the other part with at least one intermediate part. On the other hand, if any part is said to be positioned directly on another part it means that there is no intermediate part between the two parts.

According to an exemplary embodiment of the present invention, during a forming process for an STI field region in a flash memory device, a portion of a silicon oxide layer used as a pad oxide layer is partially etched before forming a trench by using a hard mask as an etch mask. The silicon oxide layer is formed below the silicon nitride layer used as the hard mask. That is, after forming a recess groove below the hard mask by partially etching the pad oxide layer, a trench is formed by etching a portion of the silicon substrate exposed by the hard mask. Subsequently, an STI field region is formed by filling the trench with an insulation layer. At this time, the edge of the STI field region may have a round shape due to the partial etching of the pad oxide layer.

FIG. 2 to FIG. 5 are cross-sectional views showing a method of forming an STI in a flash memory device according to an exemplary embodiment of the present invention.

Referring to FIG. 2, a pad oxide layer 210 and a hard mask layer are formed by depositing an oxide layer and a silicon nitride layer on a semiconductor substrate 100, such as a silicon wafer. In addition, a hard mask 250 is formed using a mask pattern and by etching for defining an active region and a field region. The hard mask 250 may include the silicon nitride layer.

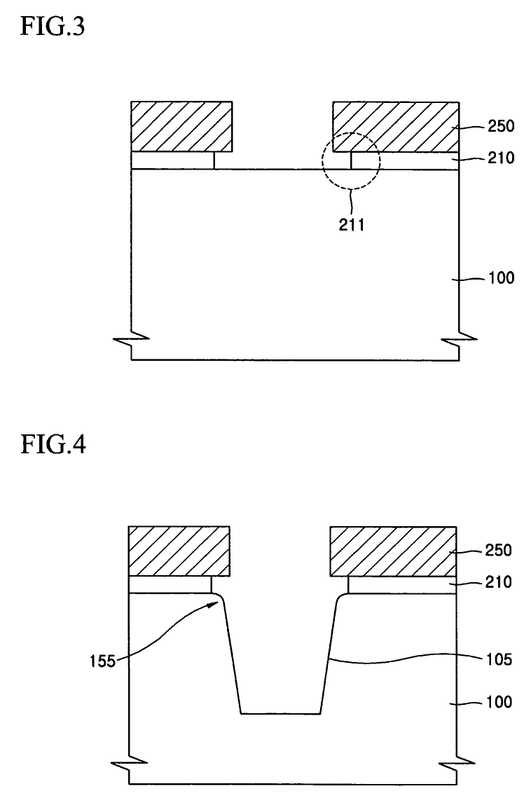

Referring to FIG. 3, a portion of the pad oxide layer 210 exposed by the hard mask 250 is etched. At this time, a portion of the pad oxide layer 210 below the hard mask 250 is additionally removed by performing isotropic etching, such as wet etching with the use of an etchant including hydrofluoric acid (HF).

Accordingly, a recess groove 211 is formed with an undercut shape. When the hydrofluoric acid wet etching is performed, an oxide layer having a thickness of about 250 Å may be used as an etching target.

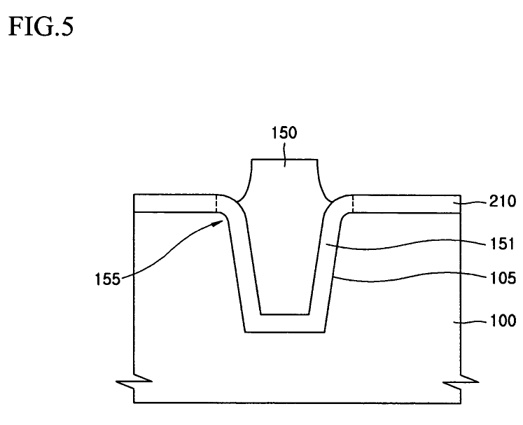

Referring to FIG. 4, a trench 105 is formed by selectively etching the exposed semiconductor substrate 100 by using the hard mask 250 as an etch mask. At this time, the etching is performed by using chemical dry etch (CDE) equipment. That is, the trench 105 is formed by isotropic dry etching. Since such a CDE process shows isotropic etching characteristics, an edge 155 of the trench 105 where the recess groove 211 is formed may have a round shape.

Referring to FIG. 5, an insulation layer 150 is formed so as to fill in the trench 105. Before forming the insulation layer 150, a buffer layer 151 may be formed on an inner wall of the trench 105 by oxidation. The insulation layer 150 filling in the trench 105 is composed of an HDP-USG (High Density Plasma-Undoped silicate glass) material.

According to an exemplary embodiment of the present invention, since an edge of an STI field region has a round profile, operation defects of a flash memory device, such as over-erase, can be prevented. Consequently, characteristics of a flash memory device may be improved.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of forming an STI in a flash memory device, comprising:
forming a pad oxide layer on a semiconductor substrate;
forming a hard mask on the pad oxide layer;
forming a recess groove below the hard mask by etching a portion of the pad oxide layer exposed by the hard mask and a portion of the pad oxide layer below the hard mask;
forming a trench having a round edge by etching a portion of the semiconductor substrate exposed by the hard mask and a portion of the semiconductor substrate exposed in the recess groove; and
forming an insulation layer filling in the trench.

2. The method of claim 1, wherein the hard mask includes a silicon nitride layer.

3. The method of claim 1, wherein the forming of the recess groove is performed by an isotropic etching process for a portion of the pad oxide layer exposed by the hard mask and a portion of the pad oxide layer below the hard mask.

4. The method of claim 3, wherein the isotropic etching for the pad oxide layer is performed by wet etching with the use of an etchant including hydrofluoric acid.

5. The method of claim 4, wherein the wet etching with the use of an etchant including hydrofluoric acid is performed by using an oxide layer having a thickness of about 250 Å as an etching target.

6. The method of claim 1, wherein the forming of the trench is performed by isotropic etching with the use of a chemical dry etch (CDE) scheme.

7. The method of claim 1, wherein the filling of the trench with the insulation layer is performed by depositing an HDP-USG (High Density Plasma-Undoped silicate glass) material.

8. The method of claim 1, wherein, before the filling of the trench with the insulation layer, a buffer layer is formed on inner walls of the trench.
